(19) United States
(12) Patent Application Publication
(10) Pub. No.: US 2012/0068269 A1
(43) Pub. Date: Mar. 22, 2012

(54) Producing a perfect P-N junction

(76) Inventor: Wen Lin, Ambler, PA (US)

(21) Appl. No.: 13/232,099

(22) Filed: Sep. 14, 2011

Related U.S. Application Data
(60) Provisional application No. 61/383,094, filed on Sep. 15, 2010.

(51) Int. Cl. H01L 27/06; H01L 21/326

(52) U.S. Cl. 257/368; 438/466; 257/E21.327; 257/E27.016

(57) ABSTRACT

This patent disclosure presents circuits, system, and method to produce an ideal memory cell and a method to produce a perfect PN junction without undesirable junction voltage and leakage current. These new inventions finally perfect the art to produce PN junction diode sixty years after PN junction diode was invented and the technology to produce an indestructible nonvolatile memory cell that is fast and small.

### CROSS REFERENCES TO RELATED APPLICATIONS

This invention is related to and the continuation of U.S. Pat. No. 7,817,459B2 issued on Oct. 19, 2010, titled “Depletion mode MOSFET circuit and applications”, invented by Wen T. Lin. This invention also claims priority from U.S. Provisional Patent application 61/383,094, titled “Producing a perfect PN junction”, invented and filed on Sep. 15, 2010 by Wen T. Lin.

### TECHNICAL FIELD

The present invention relates to the fields of both semiconductor process and circuits, and more specifically, the present invention relates to a new method of process technology to produce a PN junction without undesirable junction voltage and leakage current, and an application of this new process technology is to produce a nonvolatile memory cell that is indestructible due to erasing and writing operations.

### BACKGROUND OF INVENTION

Before PN junction diode technology became popular in the late 1940, the technology at the time was either thermion tube diode or point contact diode. The thermion tube diode is made of a cathode plate and an anode plate housed inside a vacuum tube. When a thermion tube diode is biased with a higher potential at the anode than the potential at the cathode, the amount of current flowing from anode to cathode varies linearly according the potential difference and the diode is said to be operated in the forward bias condition. A small residual current can still flow from anode to cathode when there is no potential difference between anode and cathode. The current from anode to cathode can only be stopped completely when the potential at cathode is much higher than the potential at anode and the diode is said to be operated in the reverse bias condition. Although the characteristics of thermion tube diode are perfect since the current can only flow in forward bias condition but not in reverse bias condition, its large physical size made it very undesirable. Consequently, the point contact diode was the dominant technology for the diode application at the time before PN junction diode was invented.

The structure of point contact diode is very simple; it is made of a cat whisker metal pin in contact with a piece of semiconductor wafer sitting on top of a metal plate. The simple sharp physical contact between the metal pin and semiconductor wafer amazingly produces a rectifying effect for the current. The transfer characteristics of the point contact diode operated in forward bias condition appear to be logarithmic and there is always a small leakage current when the diode is operated in reverse bias condition. The performance of point contact diode, however, is difficult to control since it depends upon the shape of physical contact between metal pin and semiconductor wafer.

When PN junction diode was invented, since the characteristics of PN junction were not affected by physical force and were more reliable and repeatable, it quickly overtook point contact diode as the mainstream technology. The PN junction diode also exhibits logarithmic transfer characteristics in the forward bias condition and a much smaller leakage current in the reverse bias condition. As illustrated in the U.S. Pat. No. 2,994,018 filed by R. N. Flail on Sep. 25, 1950, the industry accepted the logarithmic transfer characteristics and leakage current without questioning.

Theoretically, an ideal diode should be resistive in the forward bias condition so that the forward transfer characteristics should have a linear slope; since a logarithmic slope appears to be more well-defined to exhibit a turn-on voltage, the logarithmic slope was easily accepted by the industry. Additionally, the quantum physics theory predicts that there is always a junction voltage at the junction between two different materials with different work functions, since the work function of semiconductor wafer is believed to be affected by the doped impurity atoms, the turn-on voltage of a diode is thus regarded as inevitable.

A typical PN junction diode 200 as shown in FIG. 1 is made of a P-type semiconductor region 106, an N-type semiconductor region 104, a PN junction 118 and two metal-semiconductor junctions which include a metal-P junction 204 and a metal-N junction 202, with two metal leads 206 to connect the PN junction 118 to outside world. The theory of PN junction diode 200 was developed when the quantum physics theory became the official theory of solid state material science in the early years of 20^{th} century. Despite the huge progress of the semiconductor technology over the past sixty years, the PN junction diode 200 today is still about the same as the PN junction diode 200 sixty years ago and is still very far from perfect; there is always a junction voltage 190 to impede the current carrier when the PN junction diode 200 is operated in forward bias condition and there is always a leakage current 196 when the PN junction diode 200 is operated in reverse bias condition. These two problems have been in existence since the first PN junction diode 200 was made and have been around with us for so long that no one complains about them any more and takes them as granted.

The junction voltage 190 of PN junction 118 is thought to be inherent due to the difference of work function between the two regions of the same semiconductor wafer doped with different kind of impurity atoms. Although it can't be measured directly, the junction voltage 190 can be seen at work whenever current carrier flows through the PN junction 118. However, a semiconductor wafer doped with one kind of impurity atoms should have the same atomic structure as the same semiconductor wafer doped with a different kind of impurity atoms since the density of doped impurity atoms is usually at a much lower concentration than the density of atoms of semiconductor wafer. The density of doped impurity atom is typically far less than 0.1% of the density of atoms of the semiconductor wafer at the PN junction 118. So if we look at the PN junction 118 at the atomic level, there should not be any difference when the current carrier flows through the junction. The concept of junction voltage at the junction between two different materials seems logical but a junction voltage at the junction between two areas of the same semiconductor wafer doped with a low density of different impurity atoms is illogical.

The leakage current 196 of PN junction 118 is a very strange phenomenon. There is no leakage current 196 when the PN junction 118 is not biased due to a small depletion region 160 of the PN junction 118, but with a reverse bias voltage which produces a larger depletion region 160 at the PN junction 118 to impede the current carrier even more, the PN junction 118 then starts to leak. Even though a thermion tube diode has shown us that it is possible for a diode to produce no leakage current, no one was able to do so for either a PN junction diode 200 or point contact diode.

The junction voltage 190 of a PN junction 118 causes a slight inconvenience for engineers when they design circuits and the junction voltage 190 seems harmless otherwise. The leakage current 196 of PN junction 118 has been treated as a small nuisance of the real world. These minute imperfections of PN junction 118 seem irrelevant today and they never became a priority in the past. Unfortunately, since the current carriers have to waste energy overcoming the junction voltage 190 when they pass through a PN junction 118, junction voltage 190 inevitably reduces the efficiency of all electronic circuits that were built with PN junctions 118 including PN junction diodes 200, bipolar transistors, CMOS ICs, solar cells and LEDs. In the past few years, as the cost of energy soars, there is a huge demand for clean energy from solar cells and there is an urgent need to improve the efficiency of solar cells which is currently only about 15%. There is also a huge demand to improve the efficiency of lighting by replacing incandescent light bulb with LED light bulb but the heat dissipation of LED due to the junction voltage 190 is a huge problem.

The amount of leakage current 196 through a PN junction 118 is usually very small in the range of nA so that it is negligible in most applications; however, as the skill in IC manufacturing advances to fabricate a large number of PN junctions 118 on a small die, the accumulated leakage current becomes a huge problem. For example, the accumulated leakage current from 10**⁹ PN junctions 118 can reach 10 A to generate a scorching heat to melt the wafer when each PN junction 118 leaks only 10 nA.

It is about time to thoroughly understand the nature of PN junction 118 and eventually to eliminate both the junction voltage 190 and leakage current 196 of a PN junction 118 completely.

With the ability to eliminate the leakage current 196 of a PN junction 118 completely, we can then improve the existing volatile memory cell to become nonvolatile easily. Today's mainstream nonvolatile memory cell relies on a floating gate to retain the electric charges for memory. Since the floating gate must be surrounded by insulator in order to retain the electric charges when the power of system is shut down, it is very difficult to alter the electric charges stored on the floating gate during the erasing and writing operations of memory access. As a result, it usually requires a strong brute force to push charges flying across the insulator to alter the memory content.

The strong brute force used in erasing and writing operations, unfortunately, will cause damages to the insulator. As a result, the number of erasing and writing cycles that a nonvolatile memory cell employing floating gate technology can endure is limited. The nonvolatile memory cell employing floating gate technology thus imposes a threat to the reliability of system.

In contrast, all volatile memory cells, such as SRAM and DRAM, can be accessed directly without causing damage to the memory cell. As a result, all volatile memory cells do not have the reliability problem. However, since there are always some PN junctions built in every volatile memory cell inherently, all volatile memory cells consume currents due to the leakage current through reverse bias PN junctions. The electric charges stored in volatile memory cell will consequently disappear as soon as the power supply to the memory cell is lost.

The technology to complete elimination of the leakage current 196 of a PN junction 118 thus allows us to solve the volatility problem of volatile memory cell. An ideal memory cell that is nonvolatile and will not cause damage to the cell during erasing and writing operations of memory access is finally possible.

### BRIEF SUMMARY OF THE INVENTION

In the beginning of this invention, the effects of polarized dipole 130 at the PN junction 118 are investigated first. It is found that the polarized dipole 130 is resulted from the annihilation of hole and electron when a majority current carrier met with a minority current carrier during the process to dope the semiconductor wafer with different impurity atoms. Since most polarized dipoles 130 are created along the same direction as the direction of impurity atoms entering the wafer and subsequently the direction of current carrier, the residual electric field 134 of polarized dipoles 130 can interfere with the external electric field that causes the flow of current carriers.

In the semiconductor wafer, since the number of majority current carrier is much higher than the number of minority current carrier, the generation of polarized dipole 130 is determined by the minority current carrier. The effect of polarized dipoles 130 consequently is insignificant in most part of the wafer because the minority current carriers are significantly outnumbered by the majority current carrier, except in the depletion region 160 at the PN junction 118.

Since the number of majority current carrier is equal to the number of minority current carrier and the net electric field from the current carriers is zero in the depletion region 160 at the PN junction 118, the undesirable residual electric field 134 of polarized dipoles 130 at the PN junction 118 becomes a singularity and is felt by the current carriers when the current carriers cross the PN junction 118. The residual electric field 134 of polarized dipoles 130 at the PN junction 118 becomes an obstacle to impede the flow of current carriers. To overcome the resistance caused by the residual electric field 134 of polarized dipoles 130 at the PN junction 118, an external voltage source is thus needed to create an electric field to nullify the residual electric field 134 caused by polarized dipoles 130 at the PN junction 118. And the potential voltage needed from the external voltage source to nullify the residual electric field 134 of polarized dipoles 130 at the PN junction 118 is traditionally equated to the junction voltage 190.

The above conclusion regarding the effects of polarized dipole 130 can also explain the difference of junction voltage 190 between diodes made of germanium wafer and diodes made of silicon wafer. Since the atom of germanium is much larger than the atom of silicon in size, the physical size of polarized dipoles 130 in germanium wafer is much larger than the size of polarized dipoles 130 in silicon wafer. Consequently, the residual electric field 134 of polarized dipoles 130 in germanium wafer is much weaker than the residual electric field 134 of polarized dipoles 130 in silicon wafer and the junction voltage 190 of diodes made by germanium wafer is much lower than the junction voltage 190 of diodes made by silicon wafer.

The residual electric field 134 of polarized dipoles 130 is also found to interfere with the electric field produced by the reverse bias voltage. And more specifically, the polarized dipoles 130 are compressed by the electric field produced of reverse bias voltage and are heated up. The ionic bond between the ions of polarized dipole 130 becomes unstable to regenerate a pair of hole 120 and electron 122 sporadically as a result. At the moment when a pair of hole 120 and electron 122 is regenerated, the electron 122 and the hole 120 will be attracted by the two terminals that provide the reverse bias voltage instantly; the electron 122 will fly to the positive terminal while the hole 120 will fly to the negative terminal to become the leakage current 196.

With the understanding of the effects of polarized dipole 130, we know that both the junction voltage 190 and leakage current 196 are produced because the residual electric field 134 of polarized dipole 130 interferes with the external electric field, both in forward and reverse bias conditions. In other words, due to the doping process of impurity atoms into the semiconductor wafer, the direction of residual electric fields 134 of most polarized dipoles 130 are opposite to the direction of the impurity atoms entering the wafer. Since the direction of PN junction 118 is perpendicular to the gradient of the distribution of doped impurity atoms, the PN junction 118 would cross over the residual electric field 134 of many polarized dipoles 130. In theory, the net electric field at the PN junction 118 should be zero. Unfortunately, the residual electric fields 134 of polarized dipoles 130 crossed over by the PN junction 118 stigmatize the PN junction 118 so that the net electric field at the PN junction 118 will never become zero at the presence of polarized dipoles 130. The residual electric field 134 of polarized dipoles 130 becomes an obstacle for current carriers when the current carriers cross over the PN junction 118. Consequently, to eliminate the junction voltage 190 will require us to correct the direction of residual electric field 134 of polarized dipoles 130 so that the direction of residual electric field 134 of polarized dipoles 130 after being corrected will become in parallel to the direction of PN junction 118 so that the net electric field remains zero at the PN junction 118 and the residual electric field of polarized dipoles will not interfere with the external electric field any more. And we can achieve this goal by applying an external correction electric field 168 to align the direction of polarized dipoles 130 physically.

Once the direction of all the residual electric fields 134 of polarized dipoles 130 are aligned and their direction become in parallel to the PN junction 118, the net residual electric field 150 of the aligned polarized dipole 184 becomes zero at the PN junction 118 and the current carriers feel no resistance when they flow through the PN junction 118. Consequently, the external voltage source will not be needed to help the current carriers flowing through the PN junction 118 and junction voltage 190 will become zero. Furthermore, the reverse bias voltage will also not compress the aligned polarized dipoles 184 any more. Instead, the ionic bond of aligned polarized dipole 184 will be stretched and become even more stable at the presence of reverse bias voltage. Hole 120 and electron 122 regeneration will thus be avoided, so will be the leakage current 196.

This invention is described by referencing to the following figures.

### LIST OF FIGURE

FIG. 1—The PN junction diode 200 (prior art)

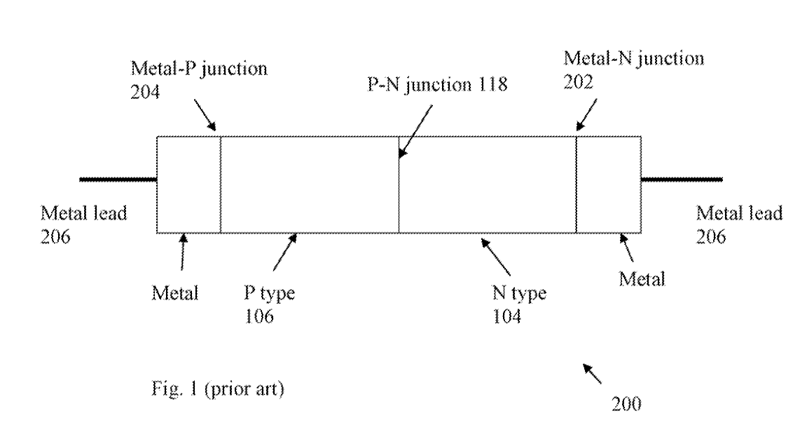

FIG. 2—The diffusion process 192 of acceptor atoms 102 diffusing into semiconductor water 170 doped with a lower concentration of donor 100 atoms. (prior art)

FIG. 3—The distribution of the concentration of diffused acceptor atoms for the diffusion process 192. (prior art)

FIG. 4—The creation of polarized dipole 130 at the PN junction 118. (prior art)

FIG. 5—The distribution of the concentration of polarized dipole for the diffusion process 192. (prior art)

FIG. 6—A drawing illustrates the method to use an external correction electric field 168 to rotate the position of the ions of polarized dipole 130 by ninety degrees to become aligned polarized dipole 184 as the embodiment 162 of this invention.

FIG. 7—A figure illustrates the generation of leakage current 196 under reversed bias condition.

FIG. 8—The 2T memory cell built with only N type depletion mode MOSFETs.

FIG. 9—A non-volatile 2T memory cell built with only N type depletion mode MOSFETs.

### BEST WAY TO IMPLEMENT THE INVENTION

### (A) PN Junction

A PN junction 118 is created when a region of semiconductor wafer 170 doped with one kind impurity atoms is in contact with another region of semiconductor wafer 170 doped with another kind of impurity atoms with opposite polarity; a PN junction 118 is created approximately at the place where the two regions meet and the concentrations of impurity atom in the two regions are equal. Since the amount of net current carrier is zero at the PN junction 118, the PN junction 118 creates a depletion region 160 due to the lack of current carrier in this region.

The most common method to produce a PN junction 118 is via substitutional diffusion process 192 to replace the atoms located at the lattice of semiconductor wafer 170 with foreign impurity atoms. The substitutional diffusion process 192 to diffuse the atoms of one material into another material in the solid phase is possible because of the random-walk behavior of atoms that creates vacancies in the lattice structure to allow the atoms of foreign impurity to slide in. Since the atoms of semiconductor wafer 170 in the solid phase must be confined to the lattice structure and do not have a large degree of freedom at room temperature, the diffusion of impurity atoms into semiconductor wafer 170 must take place in a high temperature environment when the atoms of semiconductor wafer 170 have more energy to break away from the lattice structure to produce vacancies to allow impurity atoms to slip in and diffusion to occur quickly. The vacancies theoretically are uniformly distributed inside the semiconductor wafer 170.

There are many other techniques and processes to produce a PN junction 118; for example, the ion implantation process is another popular process to produce a PN junction 118. Since the characteristics of PN junctions 118 are the same despite of the difference in process technology to produce them, although the principles and methods presented in this patent disclosure are written for the substitutional diffusion process 192, the same principles and methods can also be applied to other processes and techniques as well.

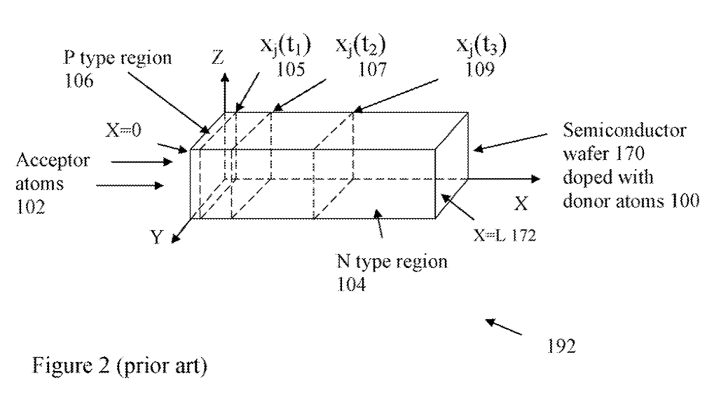

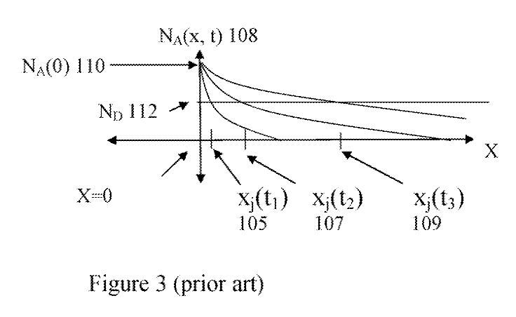

A typical substituional diffusion process 192 illustrated as in FIG. 2 starts with a semiconductor wafer 170 of length L 172 uniformly doped with a low concentration (N_{D} 112) of impurity atoms as donor 100 which offers excess electrons 122 to carry the electric current with negative charges. The region populated with donors 100 is referred to as the N type region 104 and electron 122 is the majority current carrier in this region. A high concentration (N_{A}(0) 110) of acceptor atoms 102 which offer holes 120 to carry electric current with positive charges are then diffused into the wafer 170 only through the surface at x=0. Since the acceptor atoms 102 can only diffuse into the wafer 170 when a vacancy is available at the surface of the lattice structure of the wafer 170, the substitutional diffusion process 192 is a slow process. If given enough time and assuming that the concentration of acceptor atoms 102 (N_{A}(0) 110) at the surface of wafer at x=0 remains constant throughout the whole diffusion process 192, the acceptor atoms 102 will diffuse deep into the wafer 170. The concentration of the acceptor atoms 102 diffused inside the wafer 170 at a certain time and distance from the surface at x=0 is N_{A}(x, t) 108 which is known to fall off from N_{A}(0) 110 by following the erfc function of the distance from the surface at x=0 as shown in FIG. 3.

At any given time, at some distance xⱼ(t) from the surface at x=0, the concentration of diffused acceptor atom 102 (N_{A}(xⱼ(t), t)) will be equal to the concentration of donor 100 (N_{D} 112). For the region between the surface at x=0 and xⱼ(t), the concentration of diffused acceptor atom 102 is larger than the concentration of donor 100 and for the region farther above xⱼ(t), the concentration of donor 100 is larger. The region where the concentration of diffused acceptor atoms 102 is higher is referred to as the P type region 106 and hole 120 is the majority current carrier in this region.

The substitional diffusion process 192 can be treated as a process of the movement of the PN junction 118 located at xⱼ(t). At the beginning of the diffusion process 192; xⱼ(t₁) 105 is located near the surface at x=0 and the PN junction 118 travels slowly deeper into the wafer 170 along the X axis. The traveling speed of PN junction 118 is fastest in the beginning when the concentration gradient of acceptor atoms 102 is highest. The FIGS. 2 and 3 illustrates three locations of the PN junction 118 at three different locations of xⱼ(t₁) 105, xⱼ(t₂) 107 and xⱼ(t₃) 109 at three different times of t₁, t₂ and t₃ accordingly. Since the traveling of PN junction 118 during the diffusion process 192 is along the same direction as the direction of diffusion 140 and the concentration gradient of acceptor atoms 102 determines the direction of the flow of current carriers, the direction of PN junction 118 is always perpendicular to the direction of the flow of current carriers in this example as shown in FIG. 2.

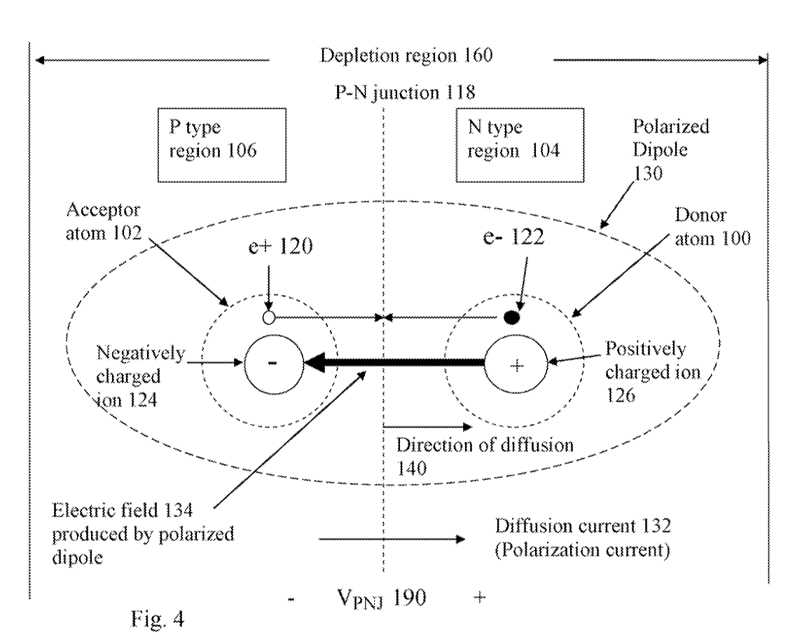

Since the P type region 106 has a higher concentration of acceptor atoms 102 than donor atoms 100, most of the electrons 122 of the donor atoms 100 originally resided in the wafer 170 before diffusion occurred would be attracted to the holes 120 of the diffused acceptor atoms 102. The electrons 122 of the donor atoms 100 would combine with holes 120 of acceptor atoms 102 and disappear due to the hole-electron annihilation to become an ionic bond so that, as a whole, the P type region 106 appears to become a region populated only with acceptors atom 102. Nevertheless, the donor atoms 100 that lost their electrons 122 still exist at where they were but simply become positively charged ions 126. At the same time, the acceptor atoms 102 that lost their holes 120 to combine with the electrons 122 of donor atoms 100 would become negatively charged ions 124. The substitutional diffusion process 192 thus creates many ion pairs bonded together by an ionic bond; the ion pair can also be called as polarized dipoles 130 as shown in FIG. 4. The concentration of polarized dipoles 130 is thus proportional to the concentration of the minority current carriers linearly.

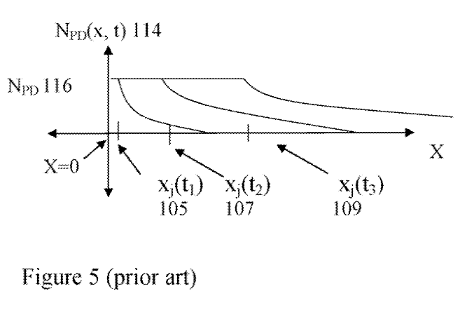

In the example as illustrated in FIG. 2, the concentration of the polarized dipoles 130 at a certain time at a certain distance from the surface at x=0 can be represented as N_{PD}(x, t) 114 as shown in FIG. 5. Since the concentration of the donor atoms 100 is constant throughout the whole wafer 170, the concentration N_{PD} 116 of the polarized dipoles 130 is also constant in the P type region 106 where donor atom 100 is the minority current carrier; but the concentration of the polarized dipoles 130 falls off according to the erfc function in the N type region 104 where the diffused acceptor atom 102 is the minority current carrier, because the concentration of diffused acceptor atoms 102 falls off from N_{A}(0) 110 according to the erfc function of the distance from the surface at x=0.

The most obvious effect of polarized dipoles 130 is that they produce a residual electric field 134 to interfere with the flow of current carrier. The creation of polarized dipole 130 in the substitutional diffusion process 192 as shown in FIG. 2 can be better explained by FIG. 4. In this figure, the hole 120 (e+) from an acceptor atom 102 is to be combined with an electron 122 (e−) from a donor atom 100 and the hole 120 is moving from left to right while the electron 122 is moving from right to left during the hole-electron annihilation process to create an ionic bond at the PN junction 118. When a hole 120 left an acceptor atom 102, it would turn the acceptor atom 102 into a negatively charged ion 124 and when an electron 122 left a donor atom 100, it would turn the donor atom 100 into a positively charged ion 126; the positively charged ion 126 and negatively charged ion 124 become a polarized dipole 130 after the annihilation of hole 120 and electron 122 has occurred. The process of hole-electron annihilation thus generates a polarization current 132 momentarily due to the movement of hole 120 and electron 122 to produce a polarized dipole 130. Since the concentration of the acceptor atom 102 is always higher in the P type region 106 on the left side of PN junction 118 and the concentration of the donor atom 100 is always higher in the N type region 104 on the right side of the PN junction 118 as shown in FIG. 4, the polarization current 132 always flows in the same direction 140 as the physical diffusion of acceptor atoms 102. The polarization current 132 only exists for a very brief moment between when the electron 122 and hole 120 starts to leave the donor atom 100 and acceptor atom 102 atom respectively and when the two charged particles combine, an ionic bond is formed or, is better called as, a polarized dipole 130 is formed. As the diffusion process 192 continues, the PN junction 118 will travel across many polarized dipoles 130 as shown in FIG. 4.

The ions of the polarized dipole 130 are usually located right next to each other and are stationary at the lattice of semiconductor wafer 170; consequently, the strength of the electric field 134 generated by most polarized dipoles 130 is the same. However, since polarized dipole 130 can also be created when the ions are further apart due to the uncertainty of the electron's orbit, as well as due to the imperfections of lattice structure, the ions of a small portion of polarized dipoles 130 may be further or closer to each other to produce weaker or stronger electric field 134. The strength of electric field 134 generated by polarized dipole 130 is thus not constant.

The strength of the far-field electric field generated by a polarized dipole 130 is inversely proportional to the third power of the distance while the strength of electric field generated by an ion is inversely proportional to the second power of distance. The far-field electric field generated by the polarized dipole 130 is thus negligible when compared with the electric field generated by the ions that produce majority current carriers. The far-field electric field generated by the polarized dipoles 130 is thus too small to be noticeable to the majority current carrier in most part of the wafer 170 where the concentration of majority current carrier is higher, except in the depletion region 160 at the PN junction 118 where the number of net current carrier is zero.

In the depletion region 160 around the PN junction 118, the number of polarized dipole 130 significantly outnumbers the number of net current carrier which is zero. Consequently, the polarized dipoles 130 dominate the electric field in the depletion region 160 around the PN junction 118. The electric field in the depletion region 160 at the PN junction 118 is especially dominated by those polarized dipoles 130 that are crossed by the PN junction 118 since these polarized dipoles 130 produce the strongest electric field 134 as illustrated in FIG. 4 to impede the flow of current carrier when the current carrier flows through the PN junction 118.

Since there is no net current carrier in the depletion region 160 at the PN junction 118, the PN junction 118 is an electrical open-circuit. The existence of a residual electric field 134 due to the polarized dipole 130 across the PN junction 118 inevitably produces a potential difference across the PN junction 118. This potential difference across the PN junction 118 is named as junction voltage (Vpnj) 190. The potential difference across the PN junction 118, however, is not measurable because this potential is produced by an open-circuit so that its impedance is infinite. The only way to measure the potential difference across the PN junction 118 is to use a voltmeter that has input impedance much higher than infinity, but this kind of voltmeter does not exist. Since the strength of the electric field 134 generated by the polarized dipole 130 at the PN junction 118 is proportional to the concentration of polarized dipole 130, which is proportional to the concentration of minority current carrier, potential difference across the PN junction 118 is determined by the concentration of the donor atom 100 originally resided in the wafer 170 before diffusion occurred. Since the concentration of donor atom 100 varies among semiconductor wafers 170 and, as explained earlier, the strength of electric field 134 generated from the polarized dipole 130 is not constant, the potential difference across the PN junction 118, or is called as the junction voltage 190, is not a constant.

Due to the lack of current carrier at the PN junction 118, it is impossible for the current carrier to flow through the PN junction 118, not to mention to overcome the extra resistance due to the residual electric field 134 of polarized dipole 130, unless there is help from outside. Applying a negative voltage −V 148 to the P type region 106 and a positive voltage +V 146 to the N type region 104 externally can create more polarized dipoles 130 and enlarge the size of depletion region 160 at the PN junction 118 because these external voltages attract the majority current carriers in opposite directions to be away from the PN junction 118 to create a large zone of negative ions in the P type region 106 and a large zone of positive ions in the N type region 104 around the PN junction 118. We call the PN junction 118 is under reverse bias condition when a negative voltage −V 148 is applied to the P type region 106 while a positive voltage +V 146 is applied to the N type region 104 at the same time. In theory, with a larger depletion region 160, no current should flow through a PN junction 118 under revere bias condition; but in fact, a very small leakage current 196 starts flowing through the PN junction 118 when a reverse bias voltage is applied. We will discuss the leakage current 196 further at the end of this application. The depletion region 160 will nevertheless return to the original state when the external voltage sources that provide the reverse bias are removed.

On the other hand, if a small positive voltage +V 146 is applied to the P type region 106 and a small negative voltage −V 148 is applied to the N type region 104 at the same time, the strength of electric field 134 generated by the polarized dipoles 130 across the PN junction 118 will be reduced because the electric field from the external voltages push more majority carriers toward the PN junction 118 to neutralize the ions of the polarized dipole 130 so that the number of polarized dipole 130 at the depletion region 160 is reduced and the size of depletion region 160 contracts. Eventually, the depletion region 160 will be completely eliminated and the electric field 134 generated by the polarized dipole 130 will be nullified if the magnitude of external voltage applied becomes large enough. Once the depletion region 160 is eliminated, current carriers will start to diffuse across the PN junction 118 and the PN junction 118 becomes conductive. Since the number of holes 120 increased in the P type region 106 at the PN junction 118 is more than the number of electrons 122 increased in the N type region 104 at the PN junction 118, because the concentration of the holes 120 in the P type region 106 is higher in this example, the current flowing through the PN junction 118 is mostly contributed by the holes 120 from the P type region 106. If the magnitude of external voltage continues to increase, the concentration of holes 120 and electrons 122 at the PN junction 118 will continue to increase so that the amount of diffusion current will increase. The higher the external voltage, the higher the concentration of holes 120 and electrons 122 at the PN junction 118 becomes and the larger the diffusion current becomes. We say that the PN junction 118 is under forward bias condition when a positive voltage +V 146 is applied to the P type region 106 and a negative voltage −V 148 is applied to the N type region 104 at the same time to produce electric current flowing through the PN junction 118. But once the external voltages are removed, the original depletion region 160 will appear again.

A PN junction 118 made of silicon wafer 170 typically requires 0.65V forward bias voltage before a noticeable current can flow through the PN junction 118; this forward bias voltage is usually equated to the junction voltage Vpnj 190 but the meanings of these two voltages are completely different. The junction voltage Vpnj 190, as explained earlier, can never be measured directly; the junction voltage Vpnj 190 can only be estimated as the forward bias voltage needed to overcome the depletion region 160 and to get current flowing through the PN junction 118.

For a diode made of a simple PN junction 118, the voltage measured at the two terminals of the diode is always zero when the two terminals are open and the current measured through the two terminals is always zero when the two terminals are shorted together. One common explanation for the inability to measure the junction voltage Vpnj 190 directly was to blame it on the junction between the wafer 170 and external metal pins and to claim that a metal-semiconductor junction voltage which has the same magnitude as the junction voltage Vpnj 190 of the PN junction 118 but with opposite polarity cancels the junction voltage Vpnj 190 of the PN junction 118. This explanation is incorrect since there is no electric field inside metal and metal is transparent to static electric charges and the junction voltage at the metal-semiconductor junction has nothing to do with the junction voltage Vpnj 190 of the PN junction 118. In theory, the metal pin should pass the exact amount of static charges induced by the potential difference across the PN junction 118 to the outside world transparently.

In a conclusion, a polarized dipole 130 is created by the diffusion process 192 of impurity atoms when the diffusion process 192 brings an acceptor atom 102 adjacent to a donor atom 100 to produce hole-electron annihilation. The polarized dipoles 130 crossed by the PN junction 118 produce a strong electric field 134 across the PN junction 118 and subsequently, a junction voltage Vpnj 190 across the PN junction 118 to impede the current carrier when the current carriers flow through the PN junction 118; a forward bias voltage is thus required to overcome the junction voltage Vpnj 190 first before the current carrier can flow through the PN junction 118. Since the junction voltage Vpnj 190 is contributed by the electric field 134 of polarized dipole 130 when the electric field 134 of polarized dipole 130 is crossed by the PN junction 118; we can come to the following conclusion immediately:

If we can prevent the PN junction 118 from crossing over the electric field 134 of polarized dipoles 130, then the polarized dipoles will not produce an electric field to impede the current carriers when the current carriers flow through the PN junction 118 and the junction voltage Vpnj 190 will not be created.

Since the polarized dipole 130 is created by the diffusion current 132 and the ions of polarized dipole 130 remain on the lattice structure after the hole-electron annihilation, there is nothing we can do to avoid the generation of polarized dipoles 130 during the diffusion process 192. Since the PN junction 118 is always located somewhere in the middle of the wafer 170 that is not accessible from outside, there is no way to know exactly where the PN junction 118 is, let alone to control it. From these facts, the only thing we can do to prevent the PN junction 118 from crossing over the electric field 134 of polarized dipoles 130 is to align the polarized dipoles physically so that the direction of the residual electric field generated by the polarized dipole becomes in parallel to the direction of PN junction 118.

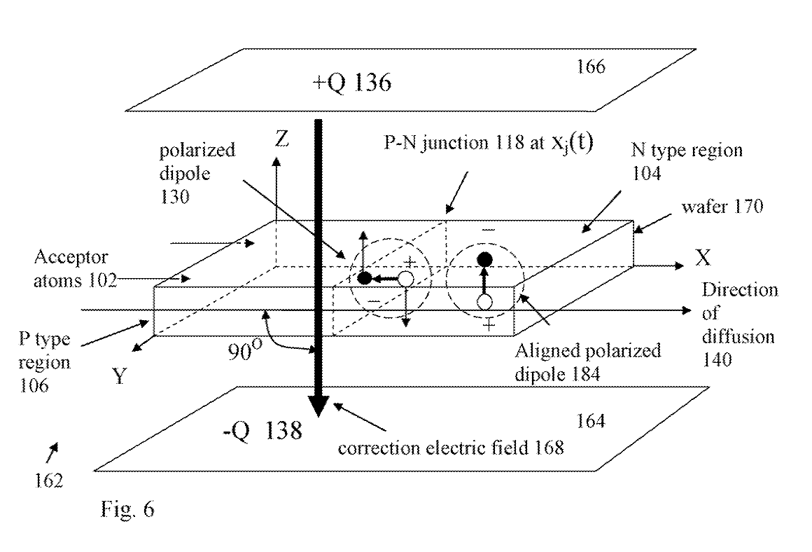

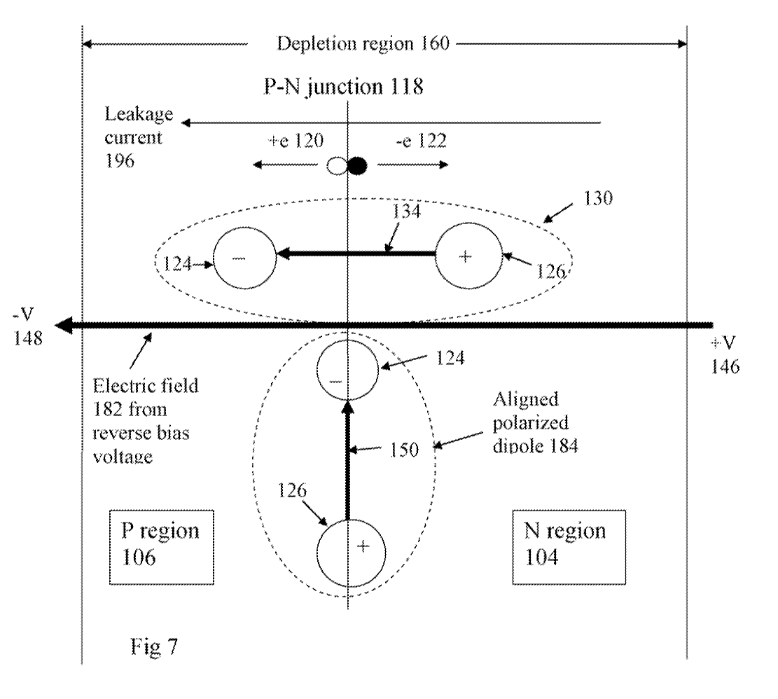

The existence of polarized dipole 130 is not the reason why junction voltage Vpnj 190 is created; the junction voltage Vpnj 190 is created because the direction of the residual electric field 134 generated by the polarized dipole 130 is in the direction against the flow of current carrier or in the direction opposite to the direction 140 of physical diffusion as in this example. If the direction of residual electric field 134 produced by the polarized dipole 130 is not in the direction against the flow of current carrier, there will be no junction voltage Vpnj 190 across the PN junction 118 to impede the current carrier and current carrier will need no help to cross the PN junction 118. Consequently, the electric field generated by the polarized dipole must be perpendicular to the direction of the flow of current carrier 140 to avoid the generation of junction voltage Vpnj 190; the polarized dipole 130 must become the aligned polarized dipole 184 as shown in FIG. 6 and FIG. 7 to avoid the generation of junction voltage Vpnj 190. This perpendicular electric field 150 generated by the aligned polarized dipole 184 will at most deflect the direction of current carrier but will not impede the current carrier when the current carrier flows through the PN junction 118 and the net electric field 150 generated by the aligned polarized dipole 184 becomes zero at the PN junction 118.

As shown in FIG. 4, since the direction of the flow of current carrier is always in the same direction 140 as the physical diffusion of impurity atoms, the diffusion current 132 that produces the polarized dipole 130 is always in the same direction 140 as physical diffusion of impurity atoms. Additionally, since the PN junction 118 is always perpendicular to the direction 140 of physical diffusion of impurity atoms, the electric field 134 generated by the polarized dipoles 130 will always be crossed by the PN junction 118—there is nothing we can do to change these natural facts. Fortunately, we can permanently alter the position of polarized dipole 130 and the direction of the residual electric field 134 generated by polarized dipole 130 after polarized dipole 130 is produced by the diffusion current 132. To do so as shown in FIG. 6, we need to apply an external correction electric field 168 across the wafer 170 and the direction of external correction electric field 168 should be perpendicular to the direction 140 of the flow of current carriers as the preferred embodiment 162 of this invention.

A correction electric field 168 can be generated between positive charges +Q 136 uniformly distributed on an X-Y plane above 166 the semiconductor wafer 170 and negative charges −Q 138 uniformly distributed on another X-Y plane below 164 the semiconductor wafer 170. If the two X-Y planes are much larger than the depletion region 160, the correction electric field 168 between the two X-Y planes will be uniformly distributed and in parallel to the Z axis and perpendicular to the direction 140 of physical diffusion which is traveling along the X axis in this example. The positive charges +Q 136 located at an X-Y plane above 166 the wafer 170 will produce a correction electric field 168 running across the wafer 170 to reach the negative charges −Q 138 located at another X-Y plane below 164 the wafer 170 and on its way down, the correction electric field 168 will twist the polarized dipole 130 by pulling the negatively charged ion 124 of the polarized dipole 130 upward while pushing the positively charged ion 126 of the polarized dipole 130 downward. If the strength of external correction electric field 168 is strong enough, the polarized dipole 130 will be forced by the external correction electric field 168 and rotated ninety degrees eventually to become the aligned polarized dipole 184. Since the external correction electric field 168 is perpendicular to the direction 140 of physical diffusion, the aligned polarized dipole 184 at its new location will also produce an electric field 150 that is perpendicular to the flow direction 140 of current carriers. Consequently, the aligned polarized dipole 184 at its new location will no longer impede the movement of current carriers when the current carriers cross the PN junction 118 and both the net electric field at the PN junction 118 and the junction voltage Vpnj 190 due to the aligned polarized dipoles 184 become zero.

The direction of external correction electric field 168 should be in the same direction as one of the three axes of the lattice structure of the semiconductor wafer 170 so that the aligned polarized dipoles 184 can stably stay at the new position permanently. Although there are infinite ways to choose a coordinate for a semiconductor wafer with lattice structure, for the best efficiency, we should choose a coordinate that produces equal and the shortest distance between atoms in at least two of the three axes that are perpendicular to each other. One of these two perpendicular axes must be in the same direction as the external correction electric field 168 and the other axis should be the same direction as the direction of physical diffusion 140 of impurity atoms.

As shown in FIG. 6, the external correction electric field 168 should be ideally generated from an AC voltage source so that the +Q 136 and −Q 138 will switch their positions at a certain rate and the direction of correction electric field 168 will alternate between up and down at the same rate as a result. If a DC voltage source is used to generate the external correction electric field 168, the correction electric field 168 might push all the polarized dipoles 130 toward one side and produce an unwanted residual electric field somewhere in the wafer.

A PN junction diode 200 made from a semiconductor wafer 170 with length of L 172 by the diffusion process 192 as illustrated in FIG. 2 will exhibit a junction voltage when metal terminals are added to the two surfaces at x=0 and x=L 172. This is because the density of the impurity atoms at the surface of x=0 and x=L 172 are different. To solve this problem, a second diffusion process for the donor atoms is needed and the donor atoms will be diffused into the wafer 170 only through the surface at x=L 172. The density of the donor atoms at the surface of x=L 172 should be the same as the density of acceptor atoms at the surface of x=0 during the first diffusion process and the size of donor atoms should be ideally the same as the size of acceptor atoms.

### (B) Leakage Current

The generation of leakage current 196 of a diode under reverse bias condition is a very puzzling phenomenon. As explained earlier, a PN junction 118 produces a small depletion region 160 which is an electrical open-circuit so that there is no current to flow through the PN junction 118 of a diode when the two terminals of the diode are shorted together. However, when an external reverse bias voltage of 2V, which is equal to the voltage difference between +V 146 at the N type region 104 and −V 148 at P type region 106 as shown in FIG. 7, is applied and the size of depletion region 160 is enlarged, theoretically, there should not be any leakage current 196 flowing from +V 146 to −V 148 at all because it has only become more difficult for current carriers to flow through a PN junction 118 under a reverse bias condition. And yet, a leakage current 196 flows through the PN junction 118 whenever a reverse bias voltage is present, even a very small reverse bias voltage introduces a noticeable leakage current 196.

The most logical explanation for this phenomenon is to blame it on the polarized dipole 130 as follows: When a polarized dipole 130 is produced by the diffusion current 132 during the diffusion process 192 and the direction of electric field 134 of the polarized dipole 130 remains unaltered and pointing in the opposite direction against the direction 140 of physical diffusion, the two ions of the polarized dipole 130 usually stay right next to each other and the ionic bond is very stable when there is no external electric field generated by bias voltage from outside. However, the polarized dipoles 130 will be subject to the influence of electric field 182 produced by the reverse bias voltages of 2V and becomes compressed and the two ions of the polarized dipole 130 will be pushed toward each other by the electric field 182 of the reverse bias voltage. The positively charged ion 126 will be pushed to the left by the electric field generated by +V 146 and the negatively charged ion 124 will be pushed to the right by the electric field generated by −V 148. The compression due to the electric field 182 from the reverse bias voltages of +V 146 and −V 148 can cause the ionic bond of polarized dipole 130 to become heated up and unstable and to regenerate a pair of hole 120 and electron 122 sporadically. Once produced, the hole 120 and electron 122 will be immediately attracted by the reverse bias voltage, the electron 122 will flow to +V 146 and the hole 120 will flow to −V 148 to become the leakage current 196 that flows from +V 146 to −V 148 through the depletion region 160. As soon as the regenerated hole 120 and electron 122 are gone, the polarized dipole 130 will become cooled down and return to the original stressed state and the whole hole-electron regeneration process repeats itself over and over again. The probability for the ionic bond of polarized dipole 130 to regenerate a hole 120 and electron 122 pair depends upon the energy of the ionic bond, and from the behaviors of leakage current 196 we observed, we know that the probability of hole-electron regeneration from polarized dipoles 130 is affected by the temperature far more than by the reverse bias voltage.

Consequently, if the above explanation is correct, then an aligned polarized dipole 184 will produce no leakage current 196 since the electric field 182 produced by the reverse bias voltages will no longer compress the ions of the aligned polarized dipole 184 toward each other. Since the aligned polarized dipole 184 produces an electric field 150 perpendicular to the directions of diffusion 140 and the flow of current carrier, the electric field 182 generated from external reversed bias voltage can only twist and stretch the ionic bond of the aligned polarized dipole 184 further apart so that ionic bond between the ions of the aligned polarized dipole 184 become even more stable than before the reverse bias voltage is applied; consequently, the ionic bond between the ions of aligned polarized dipole 184 will no longer regenerate hole 120 and electron 122 pair to produce leakage current 196 to flow through the depletion region 160 of a reverse biased PN junction 118 any more. Although the external electric field 182 from the reverse bias voltage can still press the ions of the aligned polarized dipole 184 against the adjacent regular atoms; since these ion-atom bonds can not regenerate a pair of hole and electron like an ionic bond between the two ions of polarized dipole 130, the leakage current 196 is thus completely eliminated when all the polarized dipoles 130 become aligned polarized dipoles 184.

The leakage current 196 generated from a reverse bias PN junction 118 has a very unique popping characteristic and this kind of noise is commonly named as shot noise. The shot noise is just like the noise of popcorns cooked in a microwave oven and the popping of shot noise occurs sporadically with random intensity. The shot noise is especially annoying for a low noise bipolar transistor amplifier which unfortunately requires a reverse bias PN junction for the base-collector junction.

In a conclusion, the aligned polarized dipole 184 can eliminate both the junction voltage 190 and leakage current 196 problems of the PN junction 118 at the same time.

### (C) Application

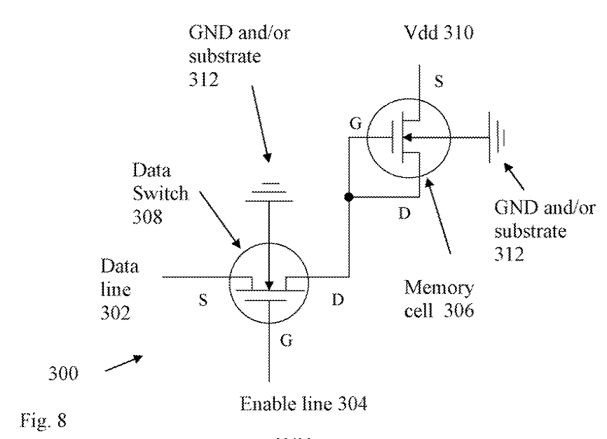

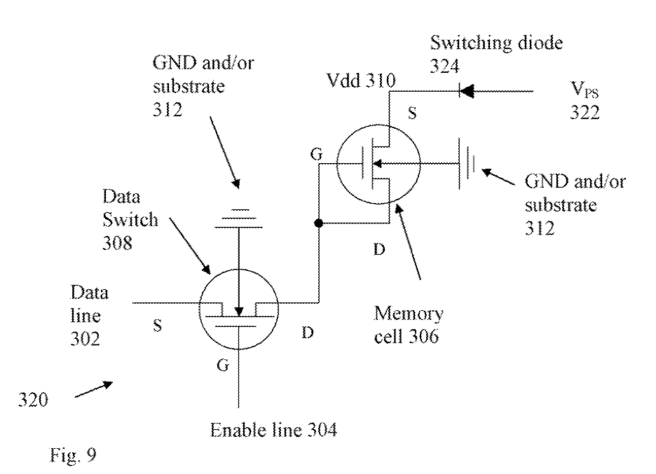

With the new technology to produce a perfect PN junction 118 without leakage current 196, we can build a non-volatile 2T memory cell easily. As shown in FIG. 8 is a regular 2T memory cell 300 made of two N type depletion mode MOSFETs. A regular 2T memory cell 300 is volatile because the moment the power supply voltage Vdd 310 is gone, the content of the memory cell 306 is lost forever. To solve this problem and to turn a volatile 2T memory cell 300 to become non-volatile, we need the addition of a power supply switching diode 324 as shown in FIG. 9. The anode of switching diode 324 is connected to the power source V_{PS} 322 while the cathode of the switching diode 324 is the power supply line Vdd 310 of the 2T memory cell 300. When the system is shutting down and the voltage of power source V_{PS} 322 is falling quickly, the switching diode 324 becomes reverse bias whenever the voltage of the power source V_{PS} 322 falls below the power supply line Vdd 310 of the memory cell. Consequently, if we disable the memory access before the voltage of power source V_{PS} 322 falls below the voltage of power supply Vdd 310 of the 2T memory cell 320, since the memory cell 320 will not draw any current when the switching diode 324 becomes reverse bias, the memory contents of the 2T memory cell 320 will thus remain at the current state forever and the memory cell becomes non-volatile.

When a “1” is stored into a memory cell 306, all the three terminals of the memory cell transistor 306 are electrically connected to Vdd 310. When a “0” is stored into a memory cell 306, the gate and source terminals of the memory cell transistor 306 are both either electrically connected the GND 312 through the data switch transistor 308 directly or floated with a potential of ground while the drain terminal is connected to Vdd 310. As a result, all PN junctions between the three terminals of the memory cell 306 and the substrate are always in reverse bias. The leakage current through the PN junctions between the three terminals of the memory cell transistor 306 and substrate should be completely eliminated by the same method to eliminate the leakage current through the switching diode 324.

### INDUSTRIAL APPLICABILITY

In the field of LED lighting, there is a pressing demand to reduce the power dissipation of LED; in the field of solar cells, there is unquenchable demand to increase the efficiency of power conversion; this new invention can accelerate the growth of these two fields instantly. In the field of memory cell, a fast and nonvolatile memory cell that is indestructible is finally possible and this new invention will define the memory technology forever.

What is claimed:

1. A method to produce a PN junction by employing a correction electric field to align the direction of the electric field of polarized dipoles.

2. The direction of the correction electric field in claim 1 is perpendicular to the direction of the flow of current carriers.

3. The direction of the correction electric field in claim 1 is the same as one of the three axes of the lattice of wafer.

4. A nonvolatile memory cell consists of a memory cell transistor, a data switch transistor and a power supply switching diode.

5. Both the memory cell transistor and the data switch transistor of claim 4 are N type depletion mode MOSFET. The drain and gate terminals of the memory cell transistor are connected together and the source terminal is connected to the cathode of the power switching diode. The anode of the power switching diode is connected to the power supply line of the system. The drain and gate terminals of the memory cell transistor are also connected to the drain terminal of the data switch transistor. The source terminal of the data switch transistor is used as the data line input while the gate terminal of the data switch transistor is used as the enable line input. The substrate terminals of both the memory cell transistor and data switch transistor are connected to ground and/or substrate.
